(19) United States
(12) Patent Application Publication
(10) Pub. No.: US 2026/0254193 A1
(43) Pub. Date: Aug. 27, 2026

(54) OPTICAL MODULE

(71) Applicant: Mitsubishi Electric Corporation, Tokyo (JP)

(72) Inventor: Yuji MASUYAMA, Tokyo (JP)

(73) Assignee: Mitsubishi Electric Corporation, Tokyo (JP)

(21) Appl. No.: 19/416,013

(22) Filed: Dec. 11, 2025

(30) Foreign Application Priority Data
Feb. 21, 2025 (JP) 2025-026380

(51) Int. Cl. H01S 5/0231; H01S 5/02212; H01S 5/02345

(52) U.S. Cl. CPC H01S 5/0231; H01S 5/02212; H01S 5/02345

(57) ABSTRACT

An optical module according to the disclosure includes a stem, a submount and a connection substrate provided on the stem, a laser, a modulator, a first high-frequency line, a termination resistor, and a termination resistor pattern connected to the termination resistor provided on the submount, a second high-frequency line provided on the connection substrate and configured to transmit a high-frequency signal to the first high-frequency line; a bump bond provided on a modulator electrode of the modulator; a first wire having one end connected to the first high-frequency line and a stitch as the other end provided on the bump bond, and a continuous wire connecting the first high-frequency line and the termination resistor pattern via the bump bond.

### BACKGROUND

### Field

The present disclosure relates to an optical module.

### BACKGROUND

Japanese Patent No. 7466773 discloses an optical module employing a CAN package. This optical module includes a stem and a pedestal portion having a bottom surface portion facing the surface of the stem, and a side surface portion along a direction perpendicular to the surface of the stem. A submount is installed on the side surface portion of the pedestal portion. A semiconductor optical integrated device including a semiconductor laser portion and an optical modulator portion is placed on the submount.

Japanese Patent No. 7466773 discloses a structure in which a high-frequency line on a connection substrate and a high-frequency line on the submount are connected by wires in order to supply a signal to the EML device mounted on the submount. Furthermore, the high-frequency line of the submount and an electrode of the EA modulator are connected by wires. In this case, for example, at high-frequency signals of 50 Gbps or higher, reflection occurs due to impedance mismatch caused by wire inductance components, which may cause deterioration of response in the high-frequency band. Increasing the number of wires can be considered to improve high-frequency characteristics. However, if the electrodes of the modulator are enlarged to secure wire connection locations, the size of the modulator increases, which may lead to an increase in the size of the optical module.

### SUMMARY

The present disclosure has been made to solve the above-mentioned problems, and an object thereof is to provide an optical module that can obtain favorable high-frequency characteristics while suppressing an increase in size.

The features and advantages of the present disclosure may be summarized as follows.

According to an aspect of the first disclosure, an optical module includes a stem having a main surface and a back surface opposite to the main surface; a lead penetrating the stem from the main surface to the back surface; a first support provided on the main surface of the stem; a submount provided on the first support; a laser and a modulator provided on the submount; a first high-frequency line provided on the submount; a termination resistor provided on the submount; a termination resistor pattern provided on the submount and connected to the termination resistor; a second support provided on the main surface of the stem; a connection substrate provided on the second support; a second high-frequency line provided on the connection substrate, and configured to receive a high-frequency signal from the lead, and transmit the high-frequency signal to the first high-frequency line; a modulator electrode provided on the modulator; a bump bond provided on the modulator electrode; a first wire having one end connected to the first high-frequency line and a stitch as the other end provided on the bump bond; and a continuous wire connecting the first high-frequency line and the termination resistor pattern via the bump bond.

According to an aspect of the second disclosure, an optical module includes a stem having a main surface and a back surface opposite to the main surface; a lead penetrating the stem from the main surface to the back surface; a first support provided on the main surface of the stem; a submount provided on the first support; a laser and a modulator provided on the submount; a first high-frequency line provided on the submount and configured to transmit a high-frequency signal to the modulator; a first ground pattern provided on the submount; a second support provided on the main surface of the stem; a connection substrate provided on the second support; a second high-frequency line provided on the connection substrate, and configured to receive the high-frequency signal from the lead, and transmit the high-frequency signal to the first high-frequency line; a second ground pattern provided on the connection substrate; and a plurality of wires connecting a pair of patterns, which are the first high-frequency line and the second high-frequency line, or the first ground pattern and the second ground pattern, wherein one end of each of the plurality of wires is connected to one of the pair of patterns, and the other end of each of the plurality of wires is provided on the other of the pair of patterns so as to overlap each other.

According to an aspect of the third disclosure, an optical module includes a stem having a main surface and a back surface opposite to the main surface; a lead penetrating the stem from the main surface to the back surface; a first support provided on the main surface of the stem; a submount provided on the first support; a laser and a modulator provided on the submount; a first high-frequency line provided on the submount and configured to transmit a high-frequency signal to the modulator; a capacitor pattern provided on the submount and electrically connected to an electrode of the modulator; a capacitor; a second support provided on the main surface of the stem; a connection substrate provided on the second support; a second high-frequency line provided on the connection substrate, and configured to receive the high-frequency signal from the lead, and transmit the high-frequency signal to the first high-frequency line; and a plurality of wires connecting the capacitor pattern and the capacitor, wherein one end of each of the plurality of wires is connected to one of the capacitor and the capacitor pattern, and the other end of each of the plurality of wires is provided on the other of the capacitor and the capacitor pattern so as to overlap each other.

According to an aspect of the fourth disclosure, an optical module includes a stem having a main surface and a back surface opposite to the main surface; a lead penetrating the stem from the main surface to the back surface; a first support provided on the main surface of the stem; a submount provided on the first support; a laser and a modulator provided on the submount; a first high-frequency line provided on the submount and configured to transmit a high-frequency signal to the modulator; a pair of first ground patterns provided on both sides of the first high-frequency line in the submount; a second support provided on the main surface of the stem; a connection substrate provided on the second support; a second high-frequency line provided on the connection substrate, and configured to receive the high-frequency signal from the lead, and transmit the high-frequency signal to the first high-frequency line; a pair of second ground patterns provided on both sides of the second high-frequency line in the connection board; and a wire connecting two patterns, which are provided on mutually opposite sides when the first high-frequency line is viewed from the second high-frequency line, among the pair of first ground patterns and the pair of second ground patterns.

According to an aspect of the fifth disclosure, an optical module includes a stem having a main surface and a back surface opposite to the main surface; a lead penetrating the stem from the main surface to the back surface; a first support provided on the main surface of the stem; a submount provided on the first support; a laser and a modulator provided on the submount; a first high-frequency line provided on the submount; a second support provided on the main surface of the stem; a connection substrate provided on the second support; a second high-frequency line provided on the connection substrate, and configured to receive a high-frequency signal from the lead, and transmit the high-frequency signal to the first high-frequency line; a modulator electrode provided on the modulator; a bump bond provided on the modulator electrode; and a connection material having conductivity, that connects the first high-frequency line and the bump bond, and has a wider width than the modulator electrode.

Other and further objects, features and advantages of the disclosure will appear more fully from the following description.

### BRIEF DESCRIPTION OF DRAWINGS

FIG. 1 is a perspective view of the optical module according to Embodiment 1.

FIG. 2 is a front view of the optical module according to Embodiment 1.

FIG. 3 is a diagram illustrating connection of the modulator electrode and the high-frequency line by the wires according to Embodiment 1.

FIG. 4 is a front view of the optical module according to a modification of Embodiment 1.

FIG. 5 is a front view of the optical module according to Embodiment 2.

FIG. 6 is a front view of the optical module according to Embodiment 3.

FIG. 7 is a front view of the optical module according to Embodiment 4.

FIG. 8 is a front view of the optical module according to Embodiment 5.

FIG. 9 is a front view of the optical module according to Embodiment 6.

FIG. 10 is a diagram illustrating the modulator electrode and the connection material according to Embodiment 6.

### DESCRIPTION OF EMBODIMENTS

The optical module according to each embodiment will be described with reference to the drawings. The same reference numerals are assigned to the same or corresponding components, and repeated description may be omitted.

### Embodiment 1

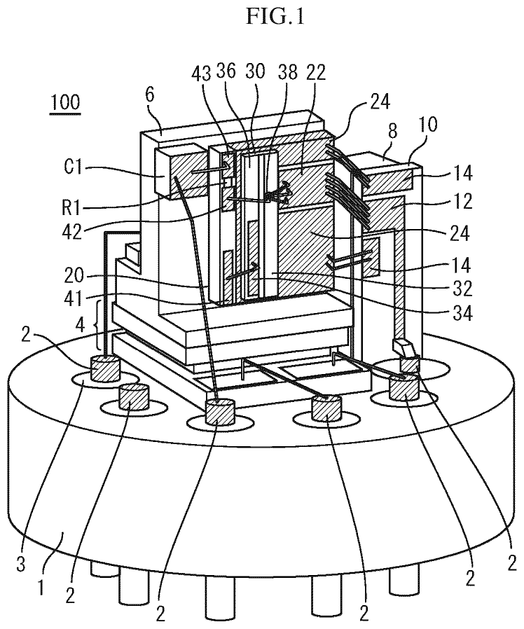

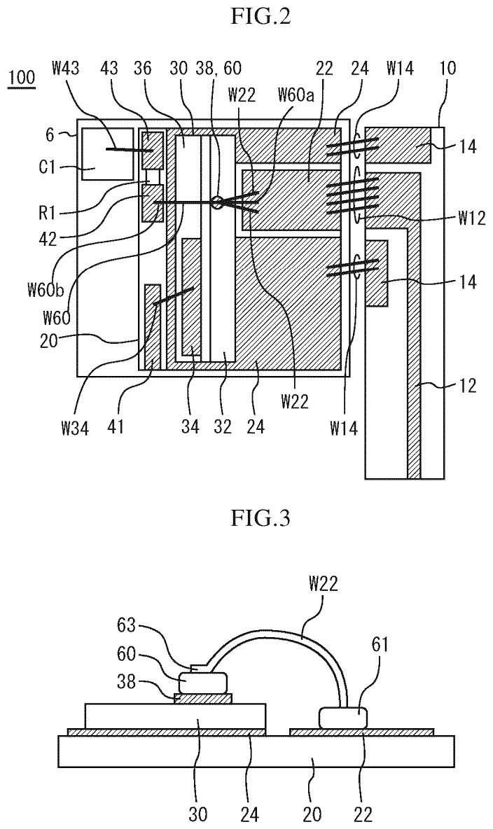

FIG. 1 is a perspective view of the optical module 100 according to Embodiment 1. FIG. 2 is a front view of the optical module 100 according to Embodiment 1. In FIG. 2, only the configuration on the support 6 and the connection substrate 10 is shown. The optical module 100 is also called a CAN-type optical module. The optical module 100 includes a stem 1 having a main surface and a back surface opposite to the main surface. The stem 1 is, for example, circular in plan view. The stem 1 is made of metal. A plurality of leads 2 penetrate the stem 1 from the main surface to the back surface. For example, glass 3 is used to fix the leads 2 to the stem 1.

A temperature control module 4 is provided on the main surface of a stem 1. The temperature control module 4 is configured such that, for example, a plurality of thermoelectric elements are sandwiched between a lower substrate and an upper substrate. A support 6 is provided on the temperature control module 4. The support 6 is also called a carrier and is formed of metal. The temperature control module 4 may be omitted, and the stem 1 and the support 6 may be one component.

A submount 20 and a capacitor C1 are provided on the support 6. The submount 20 is, for example, a dielectric substrate. The submount 20 has an optical semiconductor device 30 mounted thereon. The optical semiconductor device 30 is, for example, an EML (Electro-absorption Modulator integrated Laser diode) device. The submount 20 is supported by the support 6 and is provided such that the mounting surface of the optical semiconductor device 30 is perpendicular to the main surface of the stem 1.

A laser 32 and a modulator 36 are integrated in the optical semiconductor device 30. The modulator 36 is an EA (Electro Absorption) modulator. The laser 32 and the modulator 36 may be provided as separate elements. That is, the laser 32 and the modulator 36 only need to be provided on the submount 20. The optical semiconductor device 30 is arranged, for example, such that the extending direction of the waveguide is perpendicular to the main surface of the stem 1. A laser electrode 34 for supplying power to the laser 32 is provided on the surface of the optical semiconductor device 30. Furthermore, a modulator electrode 38 for modulating light output from the optical semiconductor device 30 by applying an electric field to the modulator 36 is provided on the surface of a portion of the optical semiconductor device 30 corresponding to the modulator 36.

A laser driving pattern 41 is provided on the mounting surface of the submount 20. The laser driving pattern 41 is connected to the laser electrode 34 via a wire W34. The laser driving pattern 41 is connected to one of the plurality of leads 2 with a wire (not shown). This makes it possible to drive the laser 32 by supplying power from the outside.

A high-frequency line 22 configured to transmit a high-frequency signal to the modulator 36 is provided on the mounting surface of the submount 20. Furthermore, a pair of ground patterns 24 is provided on both sides of the high-frequency line 22 on the mounting surface of the submount 20. The high-frequency line 22 and the ground patterns 24 constitute a coplanar line.

A termination resistor R1, a termination resistor pattern 42, and a capacitor pattern 43 are provided on the mounting surface of the submount 20. The termination resistor R1 connects the termination resistor pattern 42 and the capacitor pattern 43. The capacitor C1 is connected to the capacitor pattern 43 via a wire W43. The termination resistor R1 is connected to the ground via the capacitor C1.

A support 8 is provided on the main surface of the stem 1. The support 8 is formed of, for example, metal. The stem 1 and the support 8 may be a single component. A connection substrate 10 is provided on the support 8. The connection substrate 10 is, for example, a dielectric substrate. The connection substrate 10 is provided with a high-frequency line 12 configured to receive a high-frequency signal from a lead 2 and transmit the high-frequency signal to the high-frequency line 22. Further, a pair of ground patterns 14 are provided on both sides of the high-frequency line 12 on the connection substrate 10. The high-frequency line 12 and the ground pattern 14 constitute a coplanar line. The ground patterns 14 and 24 are grounds for a high-frequency signal line that is input to the modulator 36. According to the coplanar line, a high-frequency signal can be efficiently transmitted.

The high-frequency line 22 and the high-frequency line 12 are connected by a plurality of wires W12. Of a pair of ground patterns 14 and a pair of ground patterns 24, the patterns provided on the same side when the high-frequency line 22 is viewed from the high-frequency line 12 are connected by a plurality of wires W14.

A bump bond 60 is provided on the modulator electrode 38. A plurality of wires W22 have one ends connected to the high-frequency line 22, and the stitches at the other ends are provided on the bump bond 60. The stitches of the plurality of wires W22 are provided so as to overlap the bump bond 60. FIG. 3 is a diagram illustrating a connection between the modulator electrode 38 and the high-frequency line 22 via the wire W22 according to Embodiment 1. Note that only one wire W22 is shown in FIG. 3 for the sake of explanation. In the wire W22, a ball bond 61 is provided on the high-frequency line 22, and the stitch 63 is provided on the modulator electrode 38.

As shown in FIG. 2, the bump bond 60 and the high-frequency line 22 are further connected by a wire W60a. Also, the bump bond 60 and the termination resistor pattern 42 are connected by a wire W60b. The wire W60a and the wire W60b constitute one continuous wire W60. The continuous wire is a wire connection that connects three or more points with one wire. That is, a ball bond is formed at a 1st bond, a wedge bond is formed at a 2nd bond, and then a loop is formed without cutting the wire, and a wedge bond is further formed at another point. In this way, the continuous wire W60 connects the high-frequency line 22 and the termination resistor pattern 42 via the bump bond 60. On the bump bond 60, the stitches 63 of the plurality of wires W22 and the connection point of the continuous wire W60 overlap.

From the above, in the optical module 100, a high-frequency signal is input to the modulator 36 via the lead 2, the high-frequency line 12, the wire W12, the high-frequency line 22, the wires W22, W60a, and the modulator electrode 38.

Next, the effects of the present embodiment will be described. In conventional optical modules, for example, when a high-frequency signal of 50 Gbps or more is input, reflection occurs due to impedance mismatch caused by wire inductance components, which may cause deterioration of response in a high-frequency band. Increasing the number of wires may be considered in order to improve high-frequency characteristics. However, if the size of the modulator electrode is increased in order to secure wire connection points, the size of the modulator increases, which may hinder miniaturization. Furthermore, an increase in the size of the modulator increases the capacitance, which may deteriorate high-frequency response characteristics. Furthermore, since the electrodes for the EA modulator potentially have weak adhesion to the underlying layer, increasing the number of wires could cause the electrodes to peel off.

In contrast, in the present embodiment, the plurality of wires W22 and the continuous wire W60 are connected to the bump bond 60 provided on the modulator electrode 38. This makes it possible to suppress the size of the modulator electrode 38 while connecting a plurality of wires to the modulator 36. Therefore, miniaturization by high-density mounting and suppression of deterioration of response characteristics in a high frequency band are possible. Furthermore, the increase in load on the modulator electrode 38 can be suppressed by the bump bond 60.

Also, an intermediate point of a continuous wire generally has a smaller load on the base than a stitch. Therefore, by using the bump bond 60 as a via point for the continuous wire W60, the number of wires can be increased while suppressing an increase in the load on the modulator electrode 38. As described above, according to the present embodiment, it is possible to suppress an increase in the load on the electrodes of the modulator 36, and to suppress an increase in size and realize favorable high-frequency characteristics. Good high-frequency characteristics provide effects such as broadening of frequency characteristics and improvement of optical waveforms.

In the present embodiment, the high-frequency line 22 and the termination resistor pattern 42 are disposed on opposite sides of the modulator electrode 38. This makes it easy to linearly connect the high-frequency line 22, the termination resistor pattern 42, and the modulator electrode 38, and to form the continuous wire W60 easily. The structure, number, and arrangement of each element are not limited to those shown in FIGS. 1 and 2. For example, the number of wires W22 may be one, or may be three or more.

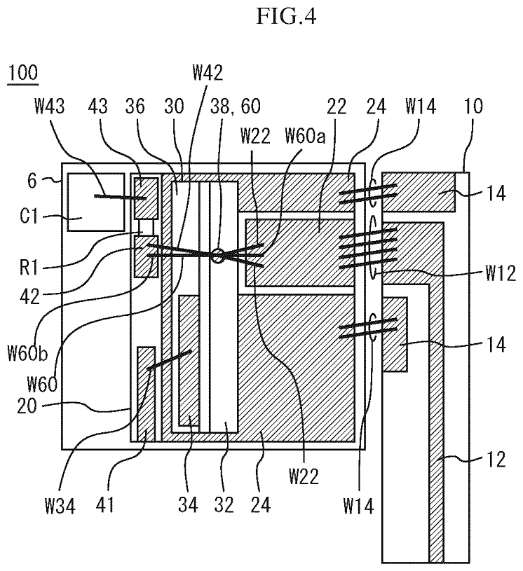

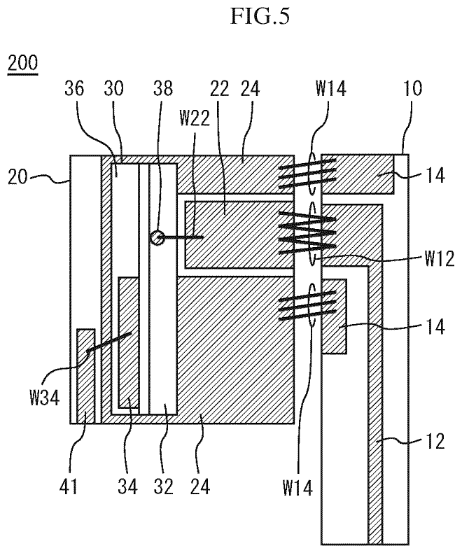

FIG. 4 is a front view of the optical module 100 according to a modification of Embodiment 1. As shown in FIG. 4, one or more wires W42 from the termination resistor R1 may be added. The wire W42 has one end connected to the termination resistor pattern 42, and a stitch, which is the other end, is provided on the bump bond 60. This makes it possible to further increase the number of wires.

The above-described modification can be applied as appropriate to the optical modules according to the following embodiments. Note that the optical modules according to the following embodiments have many points in common with Embodiment 1, and therefore, the description will focus on the differences from Embodiment 1.

### Embodiment 2

FIG. 5 is a front view of the optical module 200 according to Embodiment 2. FIG. 5 shows only the configuration on the submount 20 and the connection substrate 10. In the present embodiment, the wiring connection is different from that of Embodiment 1. In this embodiment, regarding two adjacent wires W12 among the plurality of wires W12 connecting the high-frequency line 12 and the high-frequency line 22, one ends are connected to the high-frequency line 12 so as to be separated from each other, and the other ends are provided on the high-frequency line 22 so as to overlap each other. Also, regarding other two adjacent wires W12, one ends are connected to the high-frequency line 22 so as to be separated from each other, and the other ends are provided on the high-frequency line 12 so as to overlap each other.

Thereby, the number of wires can be increased by suppressing the size of the high-frequency lines 12 and 22. Therefore, high-density mounting becomes possible, and favorable high-frequency characteristics can be obtained while suppressing an increase in size.

In FIG. 5, the plurality of wires W12 are arranged in a zigzag manner by arranging each adjacent wires W12 in a V-shape. Not limited to this, the end points of the plurality of wires W12 only need to overlap at least one location of the high-frequency line 12 or the high-frequency line 22.

Further, the wire W22 and the continuous wire W60 of Embodiment 1 may be provided in the optical module 200 of the present embodiment. Also, the termination resistor R1 and the capacitor C1 may be provided, or may be omitted.

### Embodiment 3

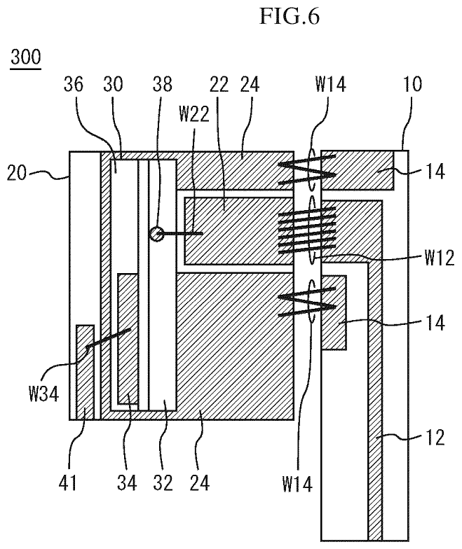

FIG. 6 is a front view of the optical module 300 according to Embodiment 3. FIG. 6 shows only the configuration on the submount 20 and the connection substrate 10. In the present embodiment, the connection of the wires is different from that in Embodiment 1. In the present embodiment, regarding two adjacent wires W14 among the plurality of wires W14 connecting the ground patterns 14 and 24, one ends are connected to the ground pattern 14 so as to be separated from each other, and the other ends are provided on the ground pattern 24 so as to overlap each other. Further, regarding other two adjacent wires W14, one ends are connected to the ground pattern 24 so as to be separated from each other, and the other ends are provided on the ground pattern 14 so as to overlap each other.

Thereby, the sizes of the ground patterns 14 and 24 can be suppressed and the number of wires can be increased. Therefore, high-density mounting becomes possible, and excellent high-frequency characteristics can be obtained while suppressing an increase in size.

In FIG. 6, the plurality of wires W14 are arranged in a zigzag manner by arranging each adjacent wires W14 in a V-shape. Not limited to this, it is sufficient that the end points of the plurality of wires W14 overlap at at least one location of the ground pattern 14 or the ground pattern 24.

From Embodiments 2 and 3, the configuration in which the end points of the wires are overlapped may be applied to a plurality of wires connecting a pair of patterns, which are the high-frequency line 12 and the high-frequency line 22 or the ground pattern 14 and the ground pattern 24. In addition, the plurality of wires W12 of Embodiment 2 may be provided in the optical module 300 of this embodiment. Furthermore, the wire W22 and the continuous wire W60 of Embodiment 1 may be provided in the optical module 200 of this embodiment. Also, the termination resistor R1 and the capacitor C1 may be provided, or may be omitted.

### Embodiment 4

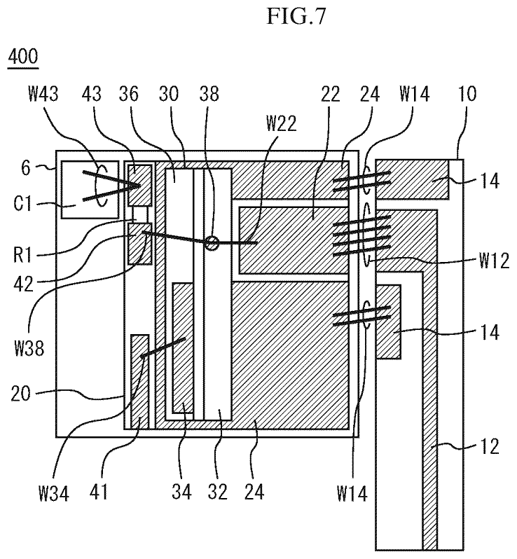

FIG. 7 is a front view of the optical module 400 according to Embodiment 4. FIG. 7 shows only the configuration on the support 6 and the connection substrate 10. In the present embodiment, the wire connection is different from that in Embodiment 1. The optical module 400 includes a plurality of wires W43 connecting a capacitor pattern 43 electrically connected to the modulator electrode 38 via the termination resistor R1 and the capacitor C1. One end of each of the plurality of wires W43 is connected to the electrode on the surface of the capacitor C1 so as to be separated from each other, and the other end is provided on the capacitor pattern 43 so as to overlap each other.

In FIG. 7, the end points of the plurality of wires W43 overlap each other on the capacitor pattern 43, but they may overlap each other on the capacitor C1. That is, one end of each of the plurality of wires W43 only needs to be connected to one of the capacitor C1 and the capacitor pattern 43, and the other end only needs to be provided on the other of the capacitor C1 and the capacitor pattern 43 so as to overlap each other.

In the present embodiment, the number of wires can be increased by suppressing the size of the capacitor pattern 43 or the capacitor C1. Therefore, high-density mounting becomes possible, and favorable high-frequency characteristics can be obtained while suppressing an increase in size.

Although two wires W43 are provided in FIG. 7, the number of wires W43 may be three or more. Further, the number of locations where the plurality of wires W43 overlap is not limited to one, and a plurality of such locations may be provided. Furthermore, the present embodiment may be combined with Embodiments 1-3.

### Embodiment 5

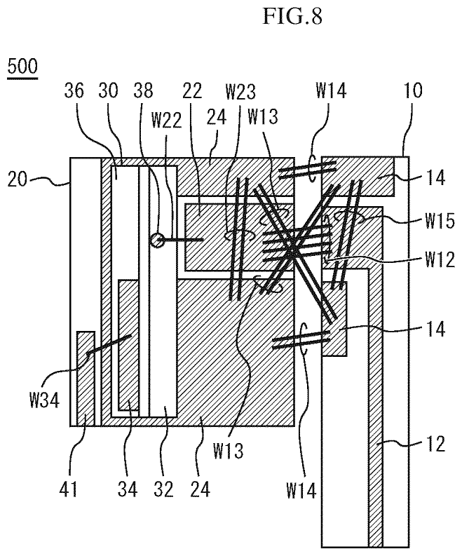

FIG. 8 is a front view of an optical module 500 according to Embodiment 5. FIG. 8 shows only the configuration on the submount 20 and the connection substrate 10. In the present embodiment, the wire connection is different from that in Embodiment 1. The optical module 500 includes wires W13, W15, and W23 that connect two patterns provided on opposite sides when the high-frequency line 22 is viewed from the high-frequency line 12, among the pair of ground patterns 14 and the pair of ground patterns 24. The wires W13, W15, and W23 are provided without contacting the high-frequency lines 12 and 22 or the wire W12.

Specifically, the wires W15 connecting the pair of ground patterns 14 and the wires W23 connecting the pair of ground patterns 24 are provided. Furthermore, the wires W13 are provided that connect a pattern provided on one side of the pair of ground patterns 24 and a pattern provided on the other side of the pair of ground patterns 14 when the high-frequency line 22 is viewed from the high-frequency line 12. Further, the wires W13 are provided that connect a pattern provided on the other side of the pair of ground patterns 24 and a pattern provided on one side of the pair of ground patterns 14 when the high-frequency line 22 is viewed from the high-frequency line 12.

According to the present embodiment, the ground potential can be stabilized, and resonance due to an electromagnetic field from the outside can be suppressed. Furthermore, since the wires W13, W15, and W23 may be connected to a ground pattern having a generally relatively large area, high-frequency characteristics can be stabilized without increasing the size of the optical module 500. Therefore, excellent high-frequency characteristics can be obtained while suppressing an increase in size.

Note that only one of the wire W15, the wire W23, and the two-way wire W13 may be provided, or two or more of them may be provided. In the example of FIG. 8, each of the wires W13, the wires W15, and the two-way wires W23 includes two wires. Not limited to this, each of the wire W15, the wire W23, and the two-way wire W13 may be a single wire, or may be a plurality of three or more wires. Note that connection with a plurality of wires is more effective.

### Embodiment 6

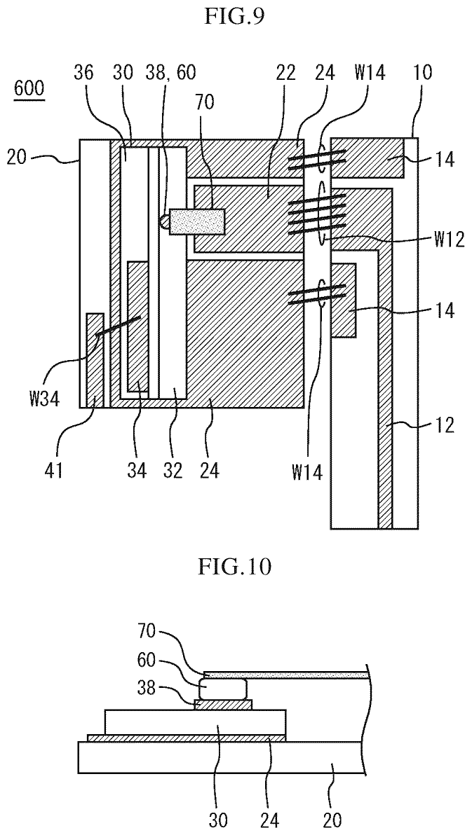

FIG. 9 is a front view of the optical module 600 according to Embodiment 6. FIG. 9 shows only the configuration on the submount 20 and the connection substrate 10. FIG. 10 is a diagram illustrating the modulator electrode 38 and a connection material 70 according to Embodiment 6. In the present embodiment, the connection between the high-frequency line 22 and the modulator electrode 38 is different from that in Embodiment 1. The bump bond 60 is provided on the modulator electrode 38. In addition, the optical module 600 includes the conductive connection material 70 that connects the high-frequency line 22 and the bump bond 60 and has a wider width than the modulator electrode 38.

In the present embodiment, by installing the bump bond 60 on the modulator electrode 38, it is possible to suppress the load on the modulator electrode 38, which potentially has weak adhesion to the base. Also, since the high-frequency line 22 and the modulator electrode 38 are connected by the connection material 70 having a wider width than the modulator electrode 38, the expansion of the modulator electrode 38 can be suppressed. Therefore, the capacitance of the optical semiconductor device 30 can be suppressed, and the deterioration of the response characteristics in a high frequency band can be suppressed. Also, high-density mounting becomes possible. Furthermore, by using the wide connection material 70, the inductance can be reduced compared to the case where a wire having the same cross-sectional area is used. Therefore, the high-frequency characteristics can be improved. From the above, also in the present embodiment, favorable high-frequency characteristics can be obtained while suppressing an increase in size.

The technical features described in each embodiment may be used in appropriate combinations.

Hereinafter, various aspects of the present disclosure will be collectively described as appendixes.

### (Appendix 1)

An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount;
a termination resistor provided on the submount;
a termination resistor pattern provided on the submount and connected to the termination resistor;
a second support provided on the main surface of the stem;
a connection substrate provided on the second support;
a second high-frequency line provided on the connection substrate, and configured to receive a high-frequency signal from the lead, and transmit the high-frequency signal to the first high-frequency line;
a modulator electrode provided on the modulator;
a bump bond provided on the modulator electrode;
a first wire having one end connected to the first high-frequency line and a stitch as the other end provided on the bump bond; and
a continuous wire connecting the first high-frequency line and the termination resistor pattern via the bump bond.

### (Appendix 2)

The optical module according to appendix 1, comprising a plurality of the first wires, wherein
the stitches of the plurality of first wires are provided so as to overlap the bump bond.
   (appendix 3)

The optical module according to appendix 1 or 2, wherein the first high-frequency line and the termination resistor pattern are disposed on opposite sides of the modulator electrode.

(appendix 4)

The optical module according to any one of appendixes 1 to 3, further comprising a second wire having one end connected to the termination resistor pattern and a stitch as the other end provided on the bump bond.

### (Appendix 5)

An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a first ground pattern provided on the submount;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line;
a second ground pattern provided on the connection substrate; and
a plurality of wires connecting a pair of patterns, which are the first high-frequency line and the second high-frequency line, or the first ground pattern and the second ground pattern, wherein
one end of each of the plurality of wires is connected to one of the pair of patterns, and the other end of each of the plurality of wires is provided on the other of the pair of patterns so as to overlap each other.

### (Appendix 6)

The optical module according to appendix 5, wherein the pair of patterns are the first high-frequency line and the second high-frequency line.

### (Appendix 7)

The optical module according to appendix 5, wherein the pair of patterns are the first ground pattern and the second ground pattern.

### (Appendix 8)

An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a capacitor pattern provided on the submount and electrically connected to an electrode of the modulator;
a capacitor;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line; and
a plurality of wires connecting the capacitor pattern and the capacitor, wherein
one end of each of the plurality of wires is connected to one of the capacitor and the capacitor pattern, and the other end of each of the plurality of wires is provided on the other of the capacitor and the capacitor pattern so as to overlap each other.

### (Appendix 9)

The optical module according to appendix 8, wherein the capacitor pattern is electrically connected to the electrode of the modulator via a termination resistor.

### (Appendix 10)

An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a pair of first ground patterns provided on both sides of the first high-frequency line in the submount;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line;
a pair of second ground patterns provided on both sides of the second high-frequency line in the connection board; and
a wire connecting two patterns, which are provided on mutually opposite sides when the first high-frequency line is viewed from the second high-frequency line, among the pair of first ground patterns and the pair of second ground patterns.

### (Appendix 11)

The optical module according to appendix 10, comprising two or more of the following wires connecting the two patterns:
a wire connecting the pair of first ground patterns;
a wire connecting the pair of second ground patterns;
a wire connecting a pattern provided on one side when the first high-frequency line is viewed from the second high-frequency line, among the pair of first ground patterns, and a pattern provided on the other side when the first high-frequency line is viewed from the second high-frequency line, among the pair of second ground patterns; and
a wire connecting a pattern provided on the other side when the first high-frequency line is viewed from the second high-frequency line, among the pair of first ground patterns, and a pattern provided on the one side when the first high-frequency line is viewed from the second high-frequency line, among the pair of second ground patterns.
   (appendix 12)

The optical module according to appendix 10 or 11, wherein the two patterns are connected by a plurality of the wires.

### (Appendix 13)

An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount;
a second support provided on the main surface of the stem;
a connection substrate provided on the second support;
a second high-frequency line provided on the connection substrate, and configured to receive a high-frequency signal from the lead, and transmit the high-frequency signal to the first high-frequency line;
a modulator electrode provided on the modulator;
a bump bond provided on the modulator electrode; and
a connection material having conductivity, that connects the first high-frequency line and the bump bond, and has a wider width than the modulator electrode.

In the optical module according to the first disclosure, the first wire and the continuous wire are connected to the bump bond provided on the modulator electrode. This makes it possible to suppress the size of the modulator electrode while connecting the plurality of wires to the modulator. Therefore, excellent high-frequency characteristics can be obtained while suppressing an increase in size of the optical module.

In the optical modules according to the second and third disclosures, the ends of the plurality of wires are provided so as to overlap on the pattern. This makes it possible to increase the number of wires while suppressing an increase in the pattern size. Therefore, excellent high-frequency characteristics can be obtained while suppressing an increase in the size of the optical module.

In the optical module according to the fourth disclosure, of the pair of first ground patterns and the pair of second ground patterns, two patterns provided on opposite sides when the first high-frequency line is viewed from the second high-frequency line are connected by the wire. By connecting the ground patterns having relatively large areas with the wire, excellent high-frequency characteristics can be obtained while suppressing an increase in the size of the optical module.

In the optical module according to the fifth disclosure, the conductive connection material having a wider width than the modulator electrode is connected to the bump bond provided on the modulator electrode. This can suppress an increase in area of the modulator electrode, and thus can suppress an increase in capacitance. Therefore, excellent high-frequency characteristics can be obtained while suppressing an increase in size of the optical module.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-026380, filed on Feb. 21, 2025 including specification, claims, drawings and summary, on which the Convention priority of the present application is based, are incorporated herein by reference in its entirety.

1. An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount;
a termination resistor provided on the submount;
a termination resistor pattern provided on the submount and connected to the termination resistor;
a second support provided on the main surface of the stem;
a connection substrate provided on the second support;
a second high-frequency line provided on the connection substrate, and configured to receive a high-frequency signal from the lead, and transmit the high-frequency signal to the first high-frequency line;
a modulator electrode provided on the modulator;
a bump bond provided on the modulator electrode;
a first wire having one end connected to the first high-frequency line and a stitch as the other end provided on the bump bond; and
a continuous wire connecting the first high-frequency line and the termination resistor pattern via the bump bond.

2. The optical module according to claim 1, comprising a plurality of the first wires, wherein
the stitches of the plurality of first wires are provided so as to overlap the bump bond.

3. The optical module according to claim 1, wherein the first high-frequency line and the termination resistor pattern are disposed on opposite sides of the modulator electrode.

4. The optical module according to claim 1, further comprising a second wire having one end connected to the termination resistor pattern and a stitch as the other end provided on the bump bond.

5. An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a first ground pattern provided on the submount;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line;
a second ground pattern provided on the connection substrate; and
a plurality of wires connecting a pair of patterns, which are the first high-frequency line and the second high-frequency line, or the first ground pattern and the second ground pattern, wherein
one end of each of the plurality of wires is connected to one of the pair of patterns, and the other end of each of the plurality of wires is provided on the other of the pair of patterns so as to overlap each other.

6. The optical module according to claim 5, wherein the pair of patterns are the first high-frequency line and the second high-frequency line.

7. The optical module according to claim 5, wherein the pair of patterns are the first ground pattern and the second ground pattern.

8. An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a capacitor pattern provided on the submount and electrically connected to an electrode of the modulator;
a capacitor;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line; and
a plurality of wires connecting the capacitor pattern and the capacitor, wherein
one end of each of the plurality of wires is connected to one of the capacitor and the capacitor pattern, and the other end of each of the plurality of wires is provided on the other of the capacitor and the capacitor pattern so as to overlap each other.

9. The optical module according to claim 8, wherein the capacitor pattern is electrically connected to the electrode of the modulator via a termination resistor.

10. An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount and configured to transmit a high-frequency signal to the modulator;
a pair of first ground patterns provided on both sides of the first high-frequency line in the submount;
a second support provided on the main surface of the stem;
a connection substrate provided on the second support;
a second high-frequency line provided on the connection substrate, and configured to receive the high-frequency signal from the lead, and transmit the high-frequency signal to the first high-frequency line;
a pair of second ground patterns provided on both sides of the second high-frequency line in the connection board; and
a wire connecting two patterns, which are provided on mutually opposite sides when the first high-frequency line is viewed from the second high-frequency line, among the pair of first ground patterns and the pair of second ground patterns.

11. The optical module according to claim 10, comprising two or more of the following wires connecting the two patterns:
a wire connecting the pair of first ground patterns;
a wire connecting the pair of second ground patterns;
a wire connecting a pattern provided on one side when the first high-frequency line is viewed from the second high-frequency line, among the pair of first ground patterns, and a pattern provided on the other side when the first high-frequency line is viewed from the second high-frequency line, among the pair of second ground patterns; and
a wire connecting a pattern provided on the other side when the first high-frequency line is viewed from the second high-frequency line, among the pair of first ground patterns, and a pattern provided on the one side when the first high-frequency line is viewed from the second high-frequency line, among the pair of second ground patterns.

12. The optical module according to claim 10, wherein the two patterns are connected by a plurality of the wires.

13. An optical module, comprising:
a stem having a main surface and a back surface opposite to the main surface;
a lead penetrating the stem from the main surface to the back surface;
a first support provided on the main surface of the stem;
a submount provided on the first support;
a laser and a modulator provided on the submount;
a first high-frequency line provided on the submount;
a second support provided on the main surface of the stem;
a connection substrate provided on the second support;
a second high-frequency line provided on the connection substrate, and configured to receive a high-frequency signal from the lead, and transmit the high-frequency signal to the first high-frequency line;
a modulator electrode provided on the modulator;
a bump bond provided on the modulator electrode; and
a connection material having conductivity, that connects the first high-frequency line and the bump bond, and has a wider width than the modulator electrode.
